(19) United States
(12) Patent Application Publication
(10) Pub. No.: US 2026/0353986 A1
(43) Pub. Date: Nov. 5, 2026

(54) DISPLAY DEVICE AND ELECTRONIC DEVICE INCLUDING THE SAME

(71) Applicant: Samsung Display Co., LTD., Yongin-si (KR)

(72) Inventors: Hwiseong Kim, Yongin-si (KR); Donghoo Kim, Yongin-si (KR); Minwoo Kim, Yongin-si (KR); Sunyoung Kim, Yongin-si (KR); Jihun Park, Yongin-si (KR); Maengha Lee, Yongin-si (KR); Jaeman Lee, Yongin-si (KR); Sangjin Choi, Yongin-si (KR); Soojeong Choi, Yongin-si (KR); Seungcheol Ha, Yongin-si (KR)

(21) Appl. No.: 19/662,641

(22) Filed: Apr. 29, 2026

(30) Foreign Application Priority Data
May 2, 2025 (KR) 10-2025-0058479

(51) Int. Cl. H10K 59/80

(52) U.S. Cl. CPC H10K 59/873

(57) ABSTRACT

A display device includes: a first substrate; a plurality of cells disposed on the first substrate, each of the plurality of cells including an active area and a pad area; a mother substrate sealant disposed along an edge of the first substrate; a main sealant disposed to surround the plurality of pad areas, which are arranged in a first direction; a filler disposed outside the main sealant; and a second substrate disposed on the filler.

This application claims priority to Korean Patent Application No. 10-2025-0058479, filed on May. 2, 2025, and all the benefits accruing therefrom under 35 U.S.C. §119, the content of which in its entirety is herein incorporated by reference.

### BACKGROUND

### 1. FIELD

One or more embodiments relate to a display device and an electronic device including the same.

### 2. DESCRIPTION OF THE RELATED ART

Display devices are used for visually displaying data. A display device may provide an image by using light-emitting diodes. The uses of display devices have been diversified, and various designs to improve the quality of display devices have been attempted.

### SUMMARY

One or more embodiments include a display device with improved reliability and quality and an electronic device including the same. However, such an objective is an example, and the scope of the disclosure is not limited thereby.

Additional aspects will be set forth in part in the description which follows and, in part, will be apparent from the description, or may be learned by practice of the presented embodiments of the disclosure.

According to one or more embodiments, a display device includes a first substrate, a plurality of cells disposed on the first substrate, each of the plurality of cells including an active area and a pad area, a mother substrate sealant disposed along an edge of the first substrate, a main sealant disposed to surround the plurality of pad areas, which are arranged in a first direction, a filler disposed outside the main sealant, and a second substrate disposed on the filler.

According to an embodiment, the main sealant may be disposed to surround at least some portion of the plurality of active areas in a plan view, and the plurality of active areas may be adjacent to the plurality of pad areas and spaced apart in a second direction crossing the first direction.

According to an embodiment, the filler may be disposed inside the mother substrate sealant.

According to an embodiment, the plurality of cells may be arranged in the first direction and the second direction.

According to an embodiment, the mother substrate sealant may have a quadrangular shape in a plan view.

According to an embodiment, the main sealant may have a quadrangular shape in a plan view.

According to an embodiment, a display element may be disposed in the active area.

According to an embodiment, drivers, which drive the display element, may be disposed in the pad area.

According to an embodiment, the filler may overlap at least some portion of the plurality of active areas in a plan view.

According to an embodiment, the filler may not overlap the pad area in a plan view.

According to an embodiment, the display device may include air bubbles arranged outside the plurality of cells.

According to an embodiment, the air bubbles may be spaced apart from each other in the first direction with the plurality of cells therebetween.

According to an embodiment, the air bubbles may not overlap the plurality of cells in a plan view.

According to one or more embodiments, an electronic device includes a first substrate, a plurality of cells disposed on the first substrate, each of the plurality of cells including an active area and a pad area, a mother substrate sealant disposed along an edge of the first substrate, a main sealant extending in a first direction, a filler disposed to overlap at least portion of the active area in a plan view, and a second substrate disposed on the filler.

According to an embodiment, the main sealant may be provided across the plurality of active areas, which are arranged in the first direction.

According to an embodiment, the main sealant and at least portion of the mother substrate sealant may be disposed to surround the filler.

According to an embodiment, the mother substrate sealant may have a quadrangular shape.

According to an embodiment, the filler may not overlap the pad area in the plan view.

According to an embodiment, the electronic device may include air bubbles arranged outside the plurality of cells.

According to an embodiment, the air bubbles may not overlap the plurality of cells in the plan view.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device according to an embodiment;

FIG. 2 is a set of schematic diagrams of electronic devices according to various embodiments;

FIG. 3 is a schematic plan view of a display device according to an embodiment;

FIG. 4 is a schematic cross-sectional view of a display device according to an embodiment;

FIG. 5 is a schematic plan view of a comparative example for comparing with an embodiment;

FIG. 6 is a schematic plan view of a display device according to another embodiment;

FIG. 7 is a schematic perspective view of a display device according to an embodiment;

FIG. 8 is a schematic equivalent circuit diagram of one sub-pixel circuit provided in a display device according to an embodiment; and

FIG. 9 is a schematic cross-sectional view of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms “first”, “second”, etc. may be used herein to describe various elements, these elements should not be limited by these terms. These elements are only used to distinguish one element from another.

In the following embodiment, as used herein, the singular forms "a," "an," and "the" are intended to include the plural forms as well, unless the context clearly indicates otherwise.

In the following embodiment, it will be further understood that the terms "comprises" and/or "comprising" used herein specify the presence of stated features or elements, but do not preclude the presence or addition of one or more other features or components.

In the following embodiment, it will be understood that when an element, such as a layer, a film, a region, or a plate, is referred to as being "on" another element, the element can be directly on the other element or intervening elements may be present thereon.

Sizes of elements in the drawings may be exaggerated for convenience of explanation. For example, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the specification, the expression such as "A and/or B" may include A, B, or A and B. The expression such as "at least one of A and B" may include A, B, or A and B.

In the following embodiment, it will be understood that when a layer, region, or element is referred to as being "connected to" another layer, region, or element, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

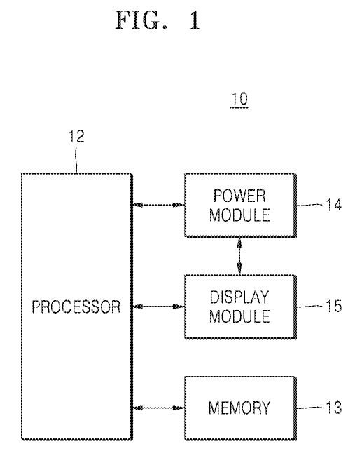

FIG. 1 is a block diagram of an electronic device 10 according to an embodiment. Referring to FIG. 1, the electronic device 10 according to an embodiment may include a display module 15, a processor 12, memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data information needed for an operation of the processor 12 or the display module 15. When the processor 12 executes an application stored in the memory 13, an image data signal and/or an input control signal is transmitted to the display module 15, and the display module 15 may process a received signal to output image information through a display screen (Note: a screen image or a display).

The power module 14 may include a power supply module, such as a power adaptor or a battery device, and a power conversion module that converts power supplied by the power supply module to generate power needed for the operation of the electronic device 10.

At least one of the respective components of the electronic device described above may be included in a display device according to the embodiments described above. Furthermore, some of individual modules functionally included in one module may be included in the display device, whereas other individual modules may be provided separately from the display device. For example, the display device may include the display module 15, and the processor 12, the memory 13, and the power module 14 may be provided in the form of other devices in the electronic device, not the display device.

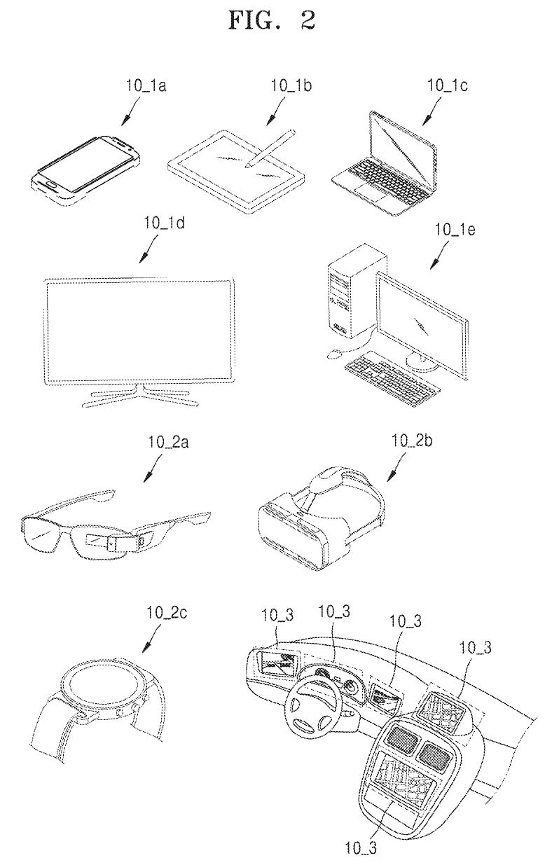

FIG. 2 is a set of schematic diagrams of electronic devices according to various embodiments.

Referring to FIG. 2, various electronic devices, to which display devices according to embodiments are applied, may include not only electronic devices for image display, such as a smartphone 10_1a, a tablet PC 10_1b, a laptop 10_1c, a TV 10_1d, or a desktop monitor 10_1e, but also wearable electronic devices including a display module, such as smart glasses 10_2a, a head mount display 10_2b, or a smart watch 10_2c, and electronic devices 10_3 for vehicles including a display module, such as an instrument panel, a center fascia, a center information display (CID) arranged on a dashboard, or a room mirror display of vehicles.

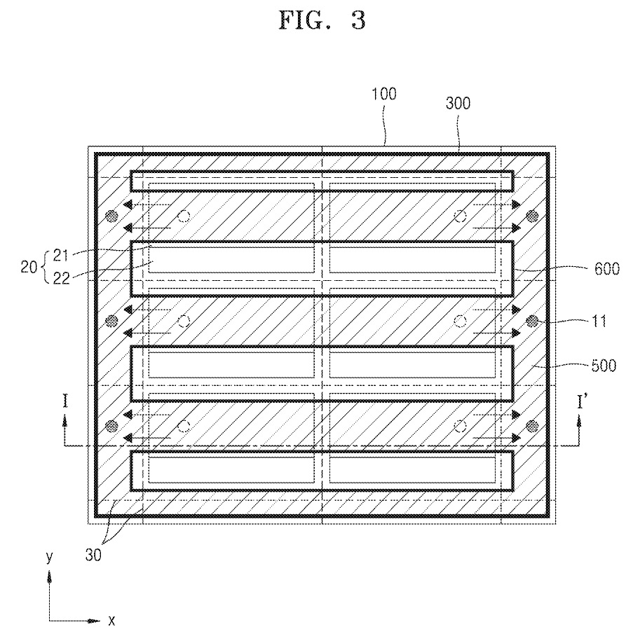

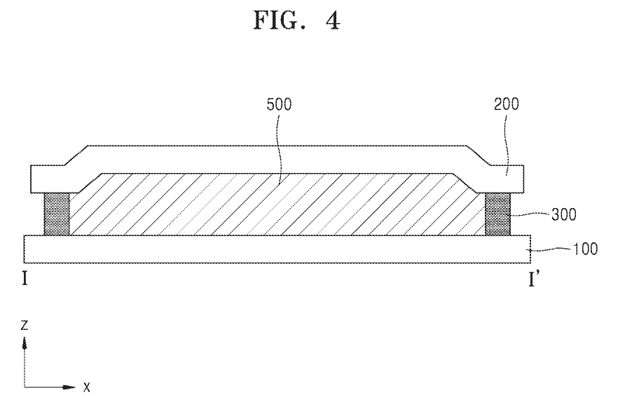

FIG. 3 is a schematic plan view of a display device according to an embodiment. FIG. 4 is a schematic cross-sectional view of a display device according to an embodiment. In detail, FIG. 4 is a schematic cross-sectional view of the display device of FIG. 3 taken along line I-I'. As used herein, the “plan view” of the display device is a view in a thickness direction (i.e., z direction) of the display device.

Referring to FIGS. 3 and 4, a plurality of cells 20 may be arranged on a first substrate 100. The plurality of cells 20 may be arranged in a first direction (e.g., an x direction or a -x direction). Furthermore, the plurality of cells 20 may be arranged in a second direction (e.g., a y direction or a -y direction). In other words, the plurality of cells 20 may be arranged in the first direction (e.g., the x direction or the -x direction) and the second direction (e.g., the y direction or the -y direction), for example, in a matrix form.

Each of the plurality of cells 20 may include an active area 21 and a pad area 22. Display elements may be arranged in the active area 21, and drivers for driving the display elements may be arranged in the pad area 22.

A mother substrate sealant 300 may be arranged along the edge of the first substrate 100. The mother substrate sealant 300 may be provided in a quadrangular shape. As the first substrate 100 has a quadrangular shape, the mother substrate sealant 300 arranged along the edge of the first substrate 100 may be provided in a quadrangular shape. The mother substrate sealant 300 may be arranged to surround the plurality of cells 20. In other words, the mother substrate sealant 300 may be arranged outside the plurality of cells 20.

A main sealant 600 may be arranged inside the mother substrate sealant 300. The main sealant 600 may be provided in a quadrangular shape. The main sealant 600 may be arranged to surround a plurality of pad areas 22 arranged in the first direction (e.g., the x direction or the -x direction). In detail, the main sealant 600 may be arranged to surround at least some of the active areas 21 spaced apart from each other in the second direction (e.g., the y direction or the -y direction) and adjacent to the pad areas 22 arranged in the first direction (e.g., the x direction or the -x direction).

A filler 500 may be arranged outside the main sealant 600. In detail, the filler 500 may be arranged outside the main sealant 600 and inside the mother substrate sealant 300. The filler 500 may overlap at least some of the active areas 21 in a plan view. As the main sealant 600 is arranged to surround the pad areas 22, the filler 500 after being ejected as a shot may not expand to the pad area 22. The filler 500 may not overlap the pad area 22 in a plan view. As the main sealant 600 prevents the filler 500 from expanding to the pad area 22, the pad area 22 where drivers are arranged may be protected from the filler 500.

A second substrate 200 may be arranged over the filler 500. The second substrate 200 may seal the display elements arranged on the first substrate 100. The second substrate 200 is formed of a transparent member so as to enable implementation of an image from the display elements, and prevents infiltration of external air and moisture into the display element. The first substrate 100 and the second substrate 200 are combined with each other by the mother substrate sealant 300 arranged at the edges thereof so as to seal a space between the first substrate 100 and the second substrate 200. The filler 500 may be arranged in the space.

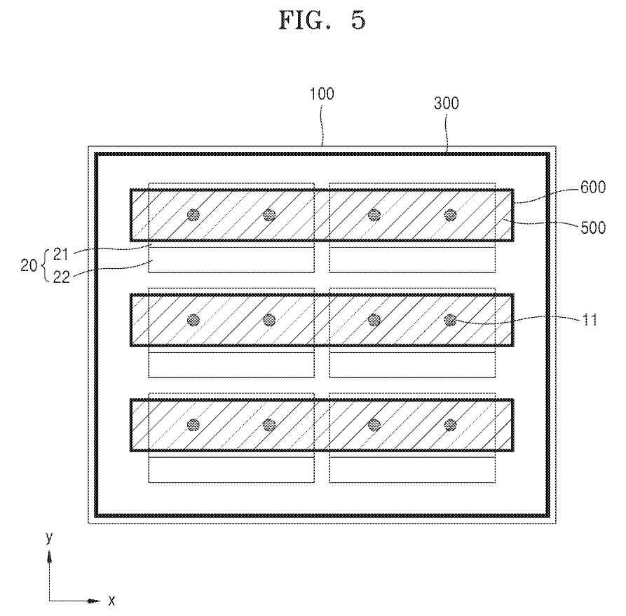

FIG. 5 is a schematic plan view of a comparative example for comparing with an embodiment.

Referring to FIG. 5, in the comparative example, after the filler 500 is ejected as a shot form onto at least portion of the first substrate 100, the first substrate 100 and the second substrate 200 may be combined with each other and the filler 500 may expand in the combination process. The filler 500 may expand to the main sealant 600.

In the process of combining the first substrate 100 and the second substrate 200, air bubbles 11 may be caught inside the filler 500 due to the internal pressure. As an area where the filler 500 is arranged is overlapped with the active area 21 in a plan view and is relatively narrow so that the internal pressure is not addressed, the air bubbles 11 may be caught inside the filler 500. In other words, as the air bubbles 11 are positioned inside the active areas 21 of the plurality of cells 20, reliability and quality of the display device may deteriorate.

Referring back to FIG. 3, in an embodiment, after the filler 500 is ejected as a shot form onto at least portion of the first substrate 100, the first substrate 100 and the second substrate 200 may be combined with each other and the filler 500 may expand in the combination process. The filler 500 may expand to the main sealant 600 and the mother substrate sealant 300.

The air bubbles 11 may be formed inside the filler 500 that expands in the process of combining the first substrate 100 and the second substrate 200. When the first substrate 100 and the second substrate 200 are combined with each other, the air bubbles 11 may be moved to the outside of the plurality of cells 20. As the area where the filler 500 is arranged is relatively large compared with the comparative example, the internal pressure is addressed, and thus the air bubbles 11 may be arranged outside the plurality of cells 20. In other words, the air bubbles 11 may be spaced apart from each other in the first direction (e.g., the x direction or the -x direction) with the plurality of cells 20 therebetween.

As the air bubbles 11 are positioned outside the plurality of cells 20, the air bubbles 11 may not be arranged inside each cell cut along a cut line 30, and quality and reliability of the display device may be improved.

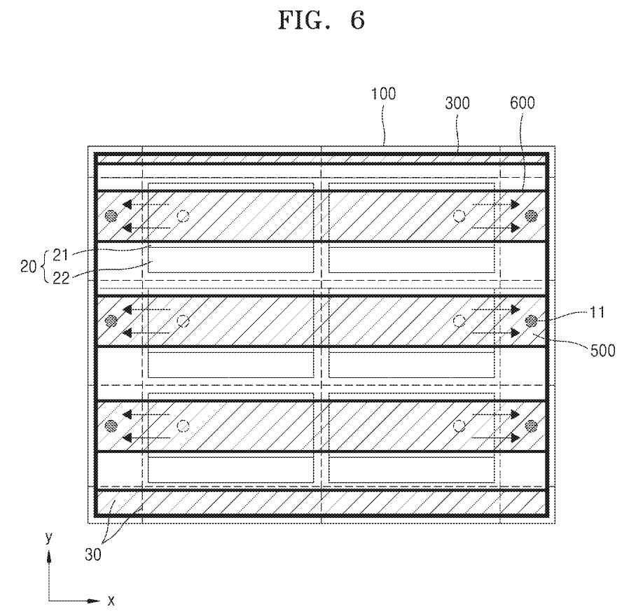

FIG. 6 is a schematic plan view of a display device according to another embodiment.

Referring to FIG. 6, the plurality of cells 20 may be arranged on the first substrate 100. The plurality of cells 20 may be arranged in the first direction (e.g., the x direction or the -x direction) and the second direction (e.g., the y direction or the -y direction).

The plurality of cells 20 may each include the active area 21 and the pad area 22. The display elements may be arranged in the active area 21, and drivers for driving the display elements may be arranged in the pad area 22.

The mother substrate sealant 300 may be arranged along the edge of the first substrate 100. The mother substrate sealant 300 may be provided in a quadrangular shape. The mother substrate sealant 300 may be arranged to surround the plurality of cells 20.

The main sealant 600 may extend in the first direction (e.g., the x direction or the -x direction). In detail, the main sealant 600 may be provided across the active areas 21 arranged in the first direction (e.g., the x direction or the -x direction).

The filler 500 may be arranged to overlap the active area 21 in a plan view. The main sealant 600 and at least portion of the mother substrate sealant 300 may be arranged to surround the filler 500. The filler 500 after being ejected as a shot may expand to the main sealant 600 and at least portion of the mother substrate sealant 300. The filler 500 may not expand to the pad area 22 due to the main sealant 600. The filler 500 may not overlap the pad area 22 in a plan view. As the filler 500 does not expand to the pad area 22 due to the main sealant 600, the pad area 22 where drivers are arranged may be protected from the filler 500.

Although it is not illustrated, the second substrate 200 may be arranged over the filler 500. The second substrate 200 may seal the display elements arranged on the first substrate 100. The first substrate 100 and the second substrate 200 are combined with each other by the mother substrate sealant 300 arranged on the edges thereof so as to seal a space between the first substrate 100 and the second substrate 200. The filler 500 may be arranged in the space.

In an embodiment, after the filler 500 is ejected as a shot form onto at least portion of the first substrate 100, the first substrate 100 and the second substrate 200 may be combined with each other and the filler 500 may expand in the combination process. The filler 500 may expand to the main sealant 600 and at least portion of the mother substrate sealant 300.

The air bubbles 11 may be formed inside the filler 500 that expands in the process of combining the first substrate 100 and the second substrate 200. When the first substrate 100 and the second substrate 200 are combined with each other, the air bubbles 11 may be moved to the outside of the plurality of cells 20. As the area where the filler 500 is arranged is relatively large compare with the comparative example illustrated in FIG. 5, the internal pressure is addressed, and thus the air bubbles 11 may be arranged outside the plurality of cells 20. In other words, the air bubbles 11 may be spaced apart from each other in the first direction (e.g., the x direction or the -x direction) with the plurality of cells 20 therebetween.

As the air bubbles 11 are positioned outside the plurality of cells 20, the air bubbles 11 may not be arranged inside each cell cut along the cut line 30, quality and reliability of the display device may be improved.

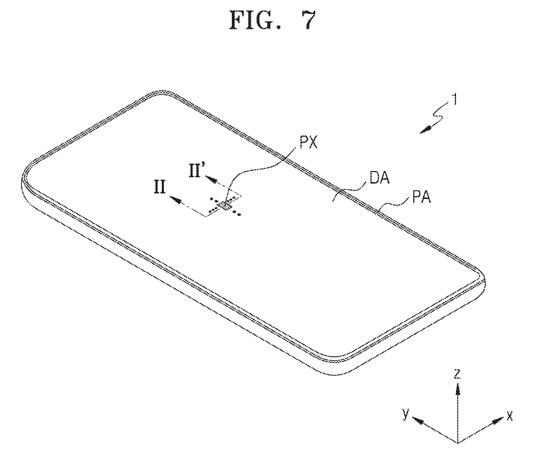

FIG. 7 is a schematic perspective view of a display device 1 according to an embodiment.

The display device 1 according to embodiments may be used, as a device for displaying a video or a still image, as display screens of various products, such as televisions, notebook computers, monitors, billboards, Internet of Things (IOT), as well as portable electronic devices, such as mobile phones, smart phones, tablet PCs (personal computers), mobile communication terminals, electronic organizers, electronic books, portable multimedia players (PMPs), navigation devices, ultra mobile PCs (UMPCs), etc. Furthermore, the display device 1 according to an embodiment may be used for wearable devices, such as smart watches, watch phones, glasses-type displays, and head mounted displays (HMDs). Furthermore, the display device 1 according to an embodiment may be used as an instrument panel of a vehicle, a center information display (CID) disposed in the center fascia or dashboard of a vehicle, a room mirror display in lieu of a side mirror of a vehicle, or a display screen disposed at the rear surface of a front seat as an entertainment device for a rear seat of a vehicle.

Referring to FIG. 7, the display device 1 may have an edge in a first direction and an edge in a second direction. The first direction and the second direction may cross each other. For example, the first direction and the second direction may form an acute angel. In another example, the first direction and the second direction may form an obtuse angle or orthogonal to each other. In the following description, a case in which the first direction and the second direction are orthogonal to each other is mainly described in detail. For example, the first direction may be the x direction or the -x direction, and the second direction may be the y direction or the -y direction. A third direction perpendicular to the first direction and the second direction may be a z direction or a -z direction.

The display device 1 may include a display area DA and a peripheral area PA outside the display area DA. The display device 1 may provide a certain image by using light emitted from a plurality of sub-pixels PXs arranged in the display area DA. The peripheral area PA is an area arranged at an outer edge of the display area DA, and may be a kind of a non-display area where the sub-pixels PXs are not arranged. The display area DA may be entirely surrounded by the peripheral area PA.

In the following description, an inorganic light-emitting display device (or an inorganic electroluminescent (EL) display device) is described as an example of the display element according to an embodiment.

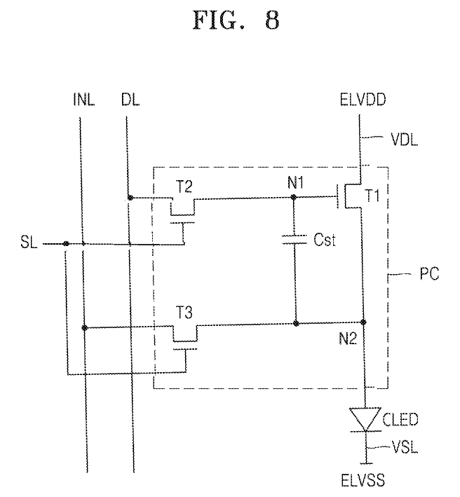

FIG. 8 is a schematic equivalent circuit diagram of one sub-pixel circuit PC provided in a display device according to an embodiment.

Referring to FIG. 8, the sub-pixel circuit PC may include a plurality of thin film transistors and at least one capacitor. In an embodiment, the sub-pixel circuit PC may include a first thin film transistor T1, a second thin film transistor T2, a third thin film transistor T3, and a storage capacitor Cst.

The first thin film transistor T1, the second thin film transistor T2, and the third thin film transistor T3 may each be an oxide semiconductor thin film transistor including a semiconductor layer formed of an oxide semiconductor, or a silicon semiconductor thin film transistor including a semiconductor layer formed of polysilicon. Each thin film transistor may include a first electrode and a second electrode, and according to the type of a thin film transistor, the first electrode may be one of a source electrode and a drain electrode, and the second electrode may be the other of the source electrode and the drain electrode. Furthermore, each thin film transistor may include a gate electrode.

The first thin film transistor T1 may be a driving thin film transistor. A first electrode of the first thin film transistor T1 may be connected to a driving voltage line VDL through which a driving power voltage ELVDD is supplied, and a second electrode of the first thin film transistor T1 may be connected to a pixel electrode of an organic light-emitting diode OLED. A gate electrode of the first thin film transistor T1 may be connected to a first node N1. The first thin film transistor T1 may control an amount of current flowing from the driving power voltage ELVDD to the organic light-emitting diode OLED in response to the voltage of the first node N1.

A second thin film transistor T2 may be a switching thin film transistor. A first electrode of the second thin film transistor T2 may be connected to a data line DL, and a second electrode of the second thin film transistor T2 may be connected to the first node N1. A gate electrode of the second thin film transistor T2 may be connected to a scan line SL. The second thin film transistor T2 may be turned on when a scan signal is supplied through the scan line SL so as to electrically connect the data line DL and the first node N1.

The third thin film transistor T3 may be an initialization thin film transistor and/or a sensing thin film transistor. A first electrode of the third thin film transistor T3 may be connected to a second node N2, and a second electrode of the third thin film transistor T3 may be connected to an initialization voltage line INL. A gate electrode of the third thin film transistor T3 may be connected to the scan line SL.

The third thin film transistor T3 may be turned on when the scan signal is supplied through the scan line SL so as to electrically connect the initialization voltage line INL and the second node N2. In some embodiments, the third thin film transistor T3 may be turned on in response to the scan signal received through the scan line SL so as to initialize the pixel electrode of the organic light-emitting diode OLED to an initialization voltage from the initialization voltage line INL.

In some embodiments, the third thin film transistor T3 may be turned on when the scan signal is supplied through the scan line SL so as to sense information about the characteristics of the organic light-emitting diode OLED. The third thin film transistor T3 may have any one or both of the function as the initialization thin film transistor and the function as the sensing thin film transistor, as described above. The initialization operation and the sensing operation of the third thin film transistor T3 may be individually or simultaneously performed. When the third thin film transistor T3 has a function as a sensing thin film transistor, the initialization voltage line INL may be referred to as a sensing line.

The storage capacitor Cst may be connected between the first node N1 and the second node N2. For example, a first capacitor plate of the storage capacitor Cst may be connected to the gate electrode of the first thin film transistor T1, and a second capacitor plate of the storage capacitor Cst may be connected to the pixel electrode of the organic light-emitting diode OLED.

A counter electrode of the organic light-emitting diode OLED may be connected to a common voltage line VSL through which a common power voltage ELVSS is provided.

Although FIG. 8 illustrates that the sub-pixel circuit PC includes three thin film transistors and one storage capacitor, the disclosure is not limited thereto. In another embodiment, the number of thin film transistors or the number of storage capacitors may vary depending on the design of the sub-pixel circuit PC.

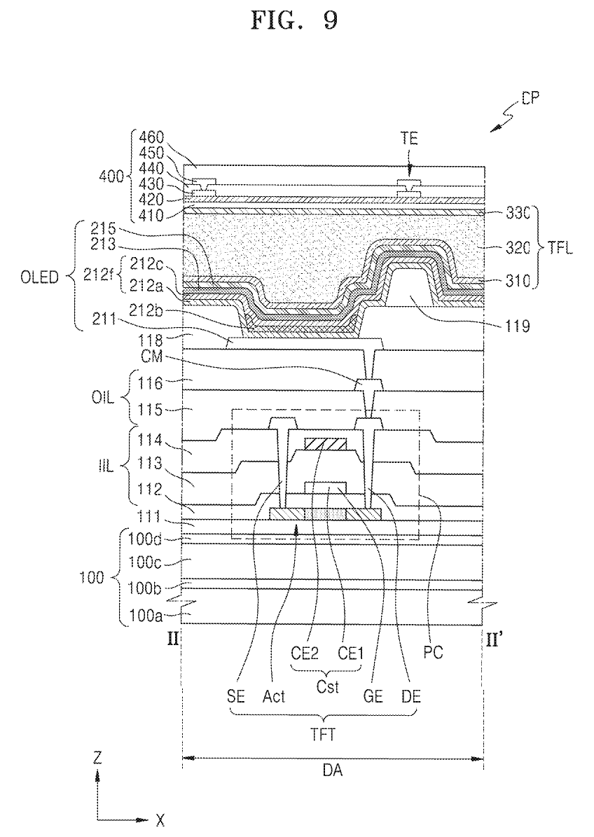

FIG. 9 is a schematic cross-sectional view of a display panel according to an embodiment.

Referring to FIG. 9, the first substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction (i.e., z direction) of the first substrate 100.

At least one of the first base layer 100a and the second base layer 100c may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer 100b and the second barrier layer 100d are barrier layers to prevent infiltration of external foreign materials, and may be a single layer or multilayer including an inorganic material, such as silicon nitride (SiNX), silicon oxide (SiO₂), and/or silicon oxynitride (SiON).

A buffer layer 111 may be disposed on the first substrate 100. The buffer layer 111 may include an inorganic insulating material, such as SiNX, SiON, and SiO₂, and may be a single layer or multilayer including the inorganic insulating material described above.

An inorganic insulating layer IIL may be disposed on the buffer layer 111. The inorganic insulating layer IIL may include a first gate insulating layer 112, a second gate insulating layer 113, and an interlayer-insulating layer 114.

The sub-pixel circuit PC may be arranged in the display area DA. The sub-pixel circuit PC may include a thin film transistor TFT and the storage capacitor Cst. The thin film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. Alternatively, the semiconductor layer Act may include amorphous silicon, oxide semiconductor, or organic semiconductor. The semiconductor layer Act may include a channel region, and a drain region and a source region that are arranged on opposite sides of the channel region.

The gate electrode GE may be disposed over the semiconductor layer Act arranged. The gate electrode GE may overlap the channel region in a plan view. The gate electrode GE may include a low resistance metal material. The gate electrode GE may include a conductive material including molybdenum (Mo), aluminum (Al), copper (Cu), or titanium (Ti), and may be formed in a multilayer or single layer including the material described above.

The first gate insulating layer 112 may be arranged between the semiconductor layer Act and the gate electrode GE. The first gate insulating layer 112 may include an inorganic insulating material, such as SiO₂, SiNX, SiON, aluminum oxide (Al₂O₃), titanium oxide (TiO₂), tantalum oxide (Ta₂O₅), hafnium oxide (HfO₂), or zinc oxide (ZnO).

The second gate insulating layer 113 may be disposed on the gate electrode GE. The second gate insulating layer 113 may be provided to cover the gate electrode GE. The second gate insulating layer 113 may include an inorganic insulating material, such as SiO₂, SiNX, SiON, Al₂O₃, TiO₂, Ta₂O₅, HfO₂, or ZnO.

A second capacitor plate CE2 of the storage capacitor Cst may be disposed on second gate insulating layer 113. The second capacitor plate CE2 may overlap the gate electrode GE positioned thereunder in a plan view. In this state, the gate electrode GE and the second capacitor plate CE2 that overlap each other with the second gate insulating layer 113 therebetween in a plan view may form the storage capacitor Cst. In other words, the gate electrode GE may function as the first capacitor plate CE1 of the storage capacitor Cst.

As such, the storage capacitor Cst and the thin film transistor TFT may overlap each other in a plan view. However, the disclosure is not limited thereto. For example, the storage capacitor Cst may be formed not to overlap the thin film transistor TFT in a plan view. In other words, the first capacitor plate CE1 of the storage capacitor Cst may be formed as a separate component from the gate electrode GE of the thin film transistor TFT to be spaced apart from the gate electrode GE of the thin film transistor TFT.

The second capacitor plate CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be a single layer or multilayer including the material described above.

The interlayer-insulating layer 114 may be disposed on the second capacitor plate CE2. The interlayer-insulating layer 114 may cover the second capacitor plate CE2. The interlayer-insulating layer 114 may include SiO₂, SiNX, SiON, Al₂O₃, TiO₂, Ta₂O₅, HfO₂, or ZnO. The interlayer-insulating layer 114 may be a single layer or multilayer including the inorganic insulating material described above.

The drain electrode DE and the source electrode SE may be disposed on the interlayer-insulating layer 114. The drain electrode DE and the source electrode SE may each be connected to the semiconductor layer Act through contact holes formed in the first gate insulating layer 112, the second gate insulating layer 113, and the interlayer-insulating layer 114. The drain electrode DE and the source electrode SE may include a highly conductive material. The drain electrode DE and the source electrode SE may include a conductive material including Mo, Al, Cu, or Ti, and may be formed in a multilayer or single layer including the material described above. For example, the drain electrode DE and the source electrode SE may have a multilayer structure of Ti/Al/Ti.

An organic insulating layer OIL may be disposed on the inorganic insulating layer IIL. The organic insulating layer OIL may include a first organic insulating layer 115 and a second organic insulating layer 116. Although FIG. 9 illustrates that two organic insulating layers OILs are provided, the disclosure is not limited thereto. The organic insulating layer OIL may include three or four organic insulating layers OILs.

The first organic insulating layer 115 may cover the drain electrode DE and the source electrode SE. The first organic insulating layer 115 may include an organic insulating material, such as a general purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

A connection electrode CM may be disposed on the first organic insulating layer 115. In this state, the connection electrode CM may be connected to the drain electrode DE or the source electrode SE through the contact hole of the first organic insulating layer 115. The connection electrode CM may include a highly conductive material. The connection electrode CM may include a conductive material including Mo, Al, Cu, or Ti, and may be formed in a multilayer or single layer including the material described above. For example, the connection electrode CM may have a multilayer structure of Ti/Al/Ti.

The second organic insulating layer 116 may be disposed on the connection electrode CM. The second organic insulating layer 116 may cover the connection electrode CM. The second organic insulating layer 116 may include the same material as or a different material from the first organic insulating layer 115.

A light-emitting diode may be disposed on the second organic insulating layer 116. For example, the organic light-emitting diode OLED may be disposed on the second organic insulating layer 116. Alternatively, although not illustrated, an inorganic light-emitting diode may be disposed on the second organic insulating layer 116.

The organic light-emitting diode OLED may emit red, green, or blue light, or red, green, blue, or white light. The organic light-emitting diode OLED may include a first electrode 211, an emission layer 212b, a functional layer 212f, a second electrode 213, and a capping layer 215. The first electrode 211 may be the pixel electrode (e.g., an anode) of the organic light-emitting diode OLED, and the second electrode 213 may be the counter electrode (e.g., a cathode) of the organic light-emitting diode OLED.

The first electrode 211 may be disposed on the second organic insulating layer 116. The first electrode 211 may be electrically connected to the connection electrode CM through a contact hole defined in the second organic insulating layer 116. The first electrode 211 may include a conductive oxide, such as indium tin oxide (ITO), indium zinc oxide (IZO), a zinc oxide (ZnO), indium oxide (In₂O₃), indium gallium oxide (IGO), or aluminum zinc oxide (AZO). In an embodiment, the first electrode 211 may include a reflective film including Ag, Mg, Al, Pt, Pd, Au, Ni, Nd, Ir, Cr, or compounds thereof. In an embodiment, the first electrode 211 may further include a film formed of ITO, IZO, ZnO, or In₂O₃ above/under the reflective film described above. For example, the first electrode 211 may have a multilayer structure of ITO/Ag/ITO.

A pixel defining layer 118 in which an opening to expose at least portion of the first electrode 211 is defined may be disposed on the first electrode 211. An emission area of light emitted from the organic light-emitting diode OLED may be defined by the opening defined in the pixel defining layer 118. For example, the width of the opening may correspond to the width of the emission area.

The pixel defining layer 118 may include an organic insulating material. Alternatively, the pixel defining layer 118 may include an inorganic insulating material, such as silicon nitride, silicon oxynitride, or silicon oxide. Alternatively, the pixel defining layer 118 may include an organic insulating material and an inorganic insulating material. In an embodiment, the pixel defining layer 118 may include a light blocking material. The light blocking material may include resin or paste including carbon black, carbon nanotubes, and a black dye, metal particles, for example, nickel, aluminum, molybdenum, and alloys thereof, metal oxide particles (e.g., chromium oxide), or metal nitride particles (e.g., chromium nitride). When the pixel defining layer 118 includes the light blocking material, reflection of external light due to metal structures disposed under the pixel defining layer 118 may be reduced.

A spacer 119 may be disposed on the pixel defining layer 118. The spacer 119 may include an organic insulating material such as polyimide. Alternatively, the spacer 119 may include an inorganic insulating material, such as SiNX or SiO₂, or both of an organic insulating material and an inorganic insulating material.

In an embodiment, the spacer 119 may include the same material as the pixel defining layer 118. In this case, the pixel defining layer 118 and the spacer 119 may be formed together in a mask process using a half-tone mask. Alternatively, the spacer 119 and the pixel defining layer 118 may include different materials.

The emission layer 212b may be disposed within the opening of the pixel defining layer 118. The emission layer 212b may include a polymer or low molecular weight organic material that emits light of a certain color.

The functional layer 212f may include a first functional layer 212a and a second functional layer 212c. The first functional layer 212a may be disposed between the first electrode 211 and the emission layer 212b, and the second functional layer 212c may be disposed between the emission layer 212b and the second electrode 213. However, at least one of the first functional layer 212a or the second functional layer 212c may be omitted. In the following description, a case in which the first functional layer 212a and the second functional layer 212c are separately disposed is mainly described in detail.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be a common layer formed to cover the entirety of the first substrate 100 like the second electrode 213 to be described below.

The second electrode 213 may be disposed on the functional layer 212f. The second electrode 213 may include a conductive material having a low work function. For example, the second electrode 213 may include a (semi-)transparent layer including Ag, Mg, Al, Pt, Pd, Au, Ni, Nd, Ir, Cr, lithium (Li), Ca, or alloys thereof. Alternatively, the second electrode 213 may further include a layer including ITO, IZO, ZnO, or In₂O₃ on the (semi-)transparent layer including the material described above.

In an embodiment, the capping layer 215 may be disposed on the second electrode 213. The capping layer 215 may include LiF, an inorganic material, or/and an organic material.

An encapsulation layer TFL may be disposed on the organic light-emitting diode OLED. The encapsulation layer TFL may cover the organic light-emitting diode OLED. The encapsulation layer TFL may be disposed on the second electrode 213 and/or the capping layer 215. In an embodiment, the encapsulation layer TFL may include at least one inorganic encapsulation layer and at least one organic encapsulation layer. FIG. 3 illustrates that the encapsulation layer TFL includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials of aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or multilayer including the material described above. The organic encapsulation layer 320 may include a polymer-based material. The polymer-based material may include acrylic resin, epoxy-based resin, polyimide, or polyethylene. In an embodiment, the organic encapsulation layer 320 may include acrylate.

An input detection layer 400 may be disposed on the encapsulation layer TFL. The input detection layer 400 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may each include an inorganic insulating material and/or an organic insulating material. For example, the first touch insulating layer 410 and the second touch insulating layer 420 may each include an inorganic insulating material, such as silicon oxide, silicon nitride, and/or silicon oxynitride.

In an embodiment, at least one of the first touch insulating layer 410 or the second touch insulating layer 420 may be omitted. For example, the first touch insulating layer 410 may be omitted. In this case, the second touch insulating layer 420 may be disposed on the second inorganic encapsulation layer 330, and the first conductive layer 430 may be disposed on the second touch insulating layer 420.

The first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. For example, the third touch insulating layer 440 may include an inorganic insulating material, such as silicon oxide, silicon nitride, and/or silicon oxynitride.

The second conductive layer 450 may be disposed on the third touch insulating layer 440. A touch electrode TE of the input detection layer 400 may be provided in a structure in which the first conductive layer 430 and the second conductive layer 450 are connected to each other. Alternatively, the touch electrode TE may be formed in one layer of the first conductive layer 430 and the second conductive layer 450, and may include a metal line provided in the corresponding conductive layer. The first conductive layer 430 and the second conductive layer 450 may each include at least one of Al, Cu, Ti, Mo, or ITO, may be a single layer or multilayer including the material described above. For example, the first conductive layer 430 and the second conductive layer 450 may each have a three-layer structure of a titanium layer / an aluminum layer / a titanium layer.

In an embodiment, the planarization layer 460 may cover the second conductive layer 450. The planarization layer 460 may include an organic insulating material.

According to the embodiment configured as described above, a display device with improved reliability and quality and an electronic device including the same may be implemented. The scope of the disclosure is not limited by the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first substrate;
a plurality of cells disposed on the first substrate, each of the plurality of cells including an active area and a pad area;
a mother substrate sealant disposed along an edge of the first substrate;
a main sealant disposed to surround the plurality of pad areas, which are arranged in a first direction;
a filler disposed outside the main sealant; and
a second substrate disposed on the filler.

2. The display device of claim 1, wherein the main sealant is disposed to surround at least some portion of the plurality of active areas in a plan view, and the plurality of active areas are adjacent to the plurality of pad areas and spaced apart in a second direction crossing the first direction.

3. The display device of claim 1, wherein the filler is disposed inside the mother substrate sealant.

4. The display device of claim 2, wherein the plurality of cells are arranged in the first direction and the second direction.

5. The display device of claim 1, wherein the mother substrate sealant has a quadrangular shape in a plan view.

6. The display device of claim 1, wherein the main sealant has a quadrangular shape in a plan view.

7. The display device of claim 1, wherein a display element is disposed in the active area.

8. The display device of claim 7, wherein drivers, which drive the display element, are disposed in the pad area.

9. The display device of claim 1, wherein the filler overlaps at least some portion of the plurality of active areas in a plan view.

10. The display device of claim 1, wherein the filler does not overlap the pad area in a plan view.

11. The display device of claim 1, further comprising air bubbles arranged outside the plurality of cells.

12. The display device of claim 11, wherein the air bubbles are spaced apart from each other in the first direction with the plurality of cells therebetween.

13. The display device of claim 11, wherein the air bubbles do not overlap the plurality of cells in a plan view.

14. An electronic device comprising:
a first substrate;
a plurality of cells disposed on the first substrate, each of the plurality of cells including an active area and a pad area;
a mother substrate sealant disposed along an edge of the first substrate;
a main sealant extending in a first direction;
a filler disposed to overlap at least portion of the active area in a plan view; and
a second substrate disposed on the filler.

15. The electronic device of claim 14, wherein the main sealant is provided across the plurality of active areas, which are arranged in the first direction.

16. The electronic device of claim 14, wherein the main sealant and at least portion of the mother substrate sealant are disposed to surround the filler.

17. The electronic device of claim 14, wherein the mother substrate sealant has a quadrangular shape.

18. The electronic device of claim 14, wherein the filler does not overlap the pad area in the plan view.

19. The electronic device of claim 14, wherein the electronic device includes air bubbles arranged outside the plurality of cells.

20. The electronic device of claim 19, wherein the air bubbles do not overlap the plurality of cells in the plan view.
